(19) United States
(12) Patent Application Publication
(10) Pub. No.: US 2026/0051462 A1
(43) Pub. Date: Feb. 19, 2026

(54) SEMICONDUCTOR PROCESSING FACILITY AND METHOD OF MANUFACTURING SEMICONDUCTOR PROCESSING FACILITY

(71) Applicant: SAMSUNG ELECTRONICS CO., LTD., SUWON-SI (KR)

(72) Inventors: Eunsook Park, Suwon-si (KR); Youngjin Noh, Suwon-si (KR); Kwangjae Lee, Suwon-si (KR); Junho Im, Suwon-si (KR); Sungwook Jung, Suwon-si (KR)

(21) Appl. No.: 19/092,156

(22) Filed: Mar. 27, 2025

(30) Foreign Application Priority Data
Aug. 16, 2024 (KR) 10-2024-0109921

(51) Int. Cl. H01J 37/32; C23C 16/44

(52) U.S. Cl. CPC H01J 37/32495; C23C 16/4405; H01J 37/32357; H01J 37/3244; H01J 2237/335

(57) ABSTRACT

A semiconductor processing facility includes a body and a tube. The body includes a base layer; a first protective layer disposed on the base layer, wherein the first protective layer having at least one of a pore portion, a pit portion, and a tunnel portion; a second protective layer disposed on the first protective layer, wherein the second protective layer fills in the at least one of the pore portion, the pit portion, and the tunnel portion; and a third protective layer disposed on the second protective layer, wherein the third protective layer defines the tube.

### CROSS-REFERENCE TO RELATED APPLICATION(S)

This application claims benefit of priority under 35 U.S.C. § 119 to Korean Patent Application No. 10-2024-0109921, filed on Aug. 16, 2024 in the Korean Intellectual Property Office, the disclosure of which is herein incorporated by reference in its entirety.

### TECHNICAL FIELD

The present inventive concept relates to a semiconductor processing facility, more specifically, to a semiconductor processing facility including a plurality of protective layers, and a manufacturing method thereof.

### DISCUSSION OF THE RELATED ART

As the electronics industry develops, there has been increasing user demand for high-performance and high-reliability semiconductor devices.

### SUMMARY

Aspects of the present inventive concept provide a semiconductor processing facility including a processing chamber having a body including a plurality of protective layers, and a method of manufacturing the semiconductor processing facility.

According to an aspect of the present inventive concept, there is provided a semiconductor processing facility including a body and a tube. The body includes a base layer; a first protective layer disposed on the base layer, wherein the first protective layer having at least one of a pore portion, a pit portion, and a tunnel portion; a second protective layer disposed on the first protective layer, wherein the second protective layer fills in the at least one of the pore portion, the pit portion, and the tunnel portion; and a third protective layer disposed on the second protective layer, wherein the third protective layer defines the tube, wherein the tube includes an injection opening and a discharge opening to facilitate filling the at least one of the pore portion, the pit portion, and the tunnel portion.

According to another aspect of the present inventive concept, there is provided a semiconductor processing facility including a plasma chamber body and a tube. The plasma chamber body includes a base layer; a first protective layer disposed on the base layer, wherein the first protective layer having at least one of a pit portion and a tunnel portion, and the tunnel portion has a first side and a second side disposed opposite to the first side; and a second protective layer disposed on the first protective layer. The second protective layer fills in at least a portion of the pit portion. The second protective layer comprises a first portion on the first side of the tunnel portion, and a second portion on the second side of the tunnel portion. A concave portion is defined by the first and second portions, between the first and second portions. The tube includes an injection opening and a discharge opening to facilitate filling the at least one of the pit portion, and the tunnel portion.

According to another aspect of the present inventive concept, there is provided a semiconductor processing facility including a plasma chamber. The plasma chamber includes a plasma chamber body; a tube, wherein the tube is defined by the plasma chamber body; a baffle plate disposed on the plasma chamber, wherein the baffle plate comprises a baffle plate body, and a first flow path communicates with the discharge opening of the plasma chamber; and a distributor on the baffle plate. The distributor includes a distributor body, and at least one second flow path communicating with the first flow path of the baffle plate. Each of the plasma chamber body, the baffle plate body, and the distributor body includes a base layer; a first protective layer disposed on the base layer, wherein the first protective layer having at least one of a pore portion, a pit portion, and a tunnel portion; a second protective layer disposed on the first protective layer, wherein the second protective layer fills in the at least one of the pore portion, the pit portion, and the tunnel portion; and a third protective layer disposed on the second protective layer, wherein the third protective layer defines the tube, wherein the tube includes an injection opening and a discharge opening to facilitate filling the at least one of the pore portion, the pit portion, and the tunnel portion.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic diagram illustrating a semiconductor processing facility according to an example embodiment of the present inventive concept;

FIG. 2 is a schematic diagram illustrating a semiconductor processing facility according to FIG. 1;

FIG. 3 is a partially enlarged view of a semiconductor processing facility according to an example embodiment, while FIG. 3 is a cross-sectional view taken along line I-I′ of FIG. 4;

FIG. 4 is a schematic plan view of some components of the semiconductor processing facility of FIG. 3;

FIG. 5 is a partially enlarged view of a semiconductor processing facility according to an example embodiment of the present inventive concept;

FIG. 6 is a partially enlarged view of a semiconductor processing facility according to an example embodiment of the present inventive concept;

FIG. 7 is a graph illustrating a comparison between a deposition rate over processing time of a semiconductor processing facility according to the related art and a deposition rate over processing time of a semiconductor processing facility according to an example embodiment of the present inventive concept;

FIG. 8 is a graph illustrating a comparison between a percentage of a fluorine element concentration over etching time of a semiconductor processing facility according to the related art and a percentage of a fluorine element concentration over etching time of a semiconductor processing facility according to an example embodiment of the present inventive concept;

FIGS. 9, 10, and 11 are cross-sectional views of sequential processes in a method of manufacturing a semiconductor processing facility according to an example embodiment of the present inventive concept;

FIGS. 12 and 13 are cross-sectional views of sequential processes in a method of manufacturing a semiconductor processing facility according to an example embodiment of the present inventive concept.

### DETAILED DESCRIPTION OF THE EMBODIMENTS

Hereinafter, the terms such as “top,” “upper portion,” “upper surface,” “above,” “bottom,” “lower portion,” “lower surface,” “below,” and “side surface” may be understood as being referred to, based on the drawings, except for being denoted by reference numerals. The terms such as “upper,” “intermediate,” and “lower” may be replaced by other terms, for example, “first,” “second,” and “third,” and may be used to describe components used herein. The terms such as “first,” “second,” and “third” may be used to describe various components, but the above-described components are not limited by the above-described terms, and a “first component” may be referred to as a “second component.”Hereinafter, preferred example embodiments of the present inventive concept will be described with reference to the accompanying drawings.

Example embodiments of the present inventive concept relate to a semiconductor processing facility and its manufacturing method, aimed at increasing the reliability of high-performance semiconductor device production. According to an embodiment of the present inventive concept, the semiconductor processing facility may include multiple protective layers.

According to this approach, the plurality of protective layers may cover potential defects, such as pinhole potion, pit portion, and tunnel portion, thereby minimizing an exposure of a substrate layer and reducing a surface roughness.

More specifically, by minimizing the exposure of the substrate layer, a degradation of the substrate layer due to a cleaning gas component may be prevented, extending the lifespan of the semiconductor process facility.

Furthermore, by reducing the surface roughness, the absorption of processing gas by the facility body may be minimized. As a result, the amount of processing gas flowing into each processing chamber remains consistent with the initial gas injection, improving process uniformity.

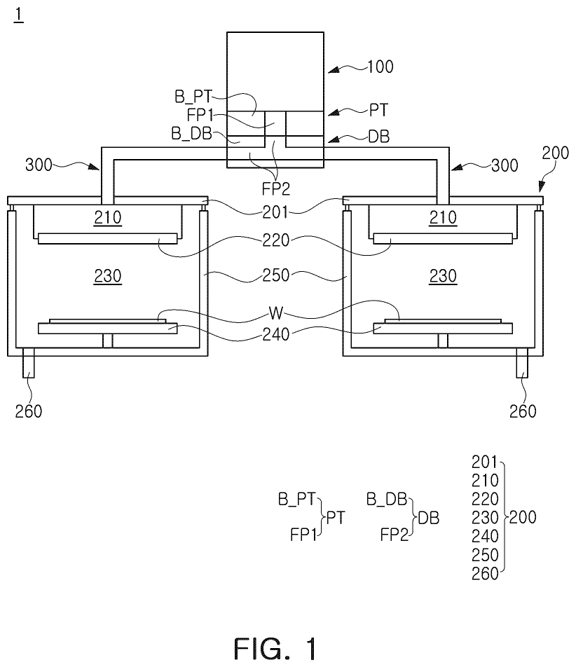

FIG. 1 is a schematic diagram illustrating a semiconductor processing facility 1 according to an example embodiment of the present inventive concept.

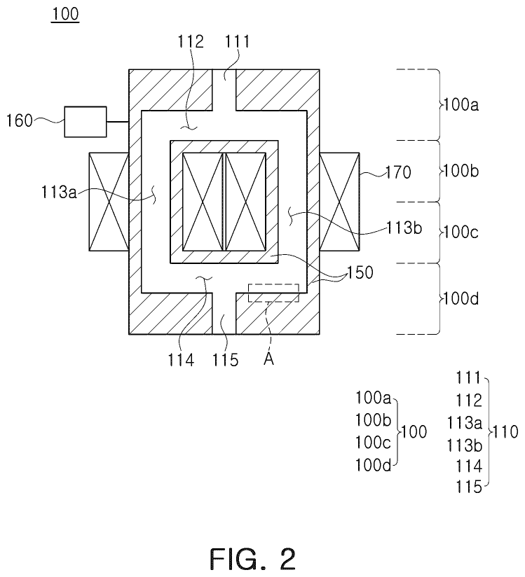

FIG. 2 is a schematic diagram illustrating a semiconductor processing facility 1 according to FIG. 1. FIG. 2 may be a schematic diagram illustrating a first processing chamber 100 of FIG. 1.

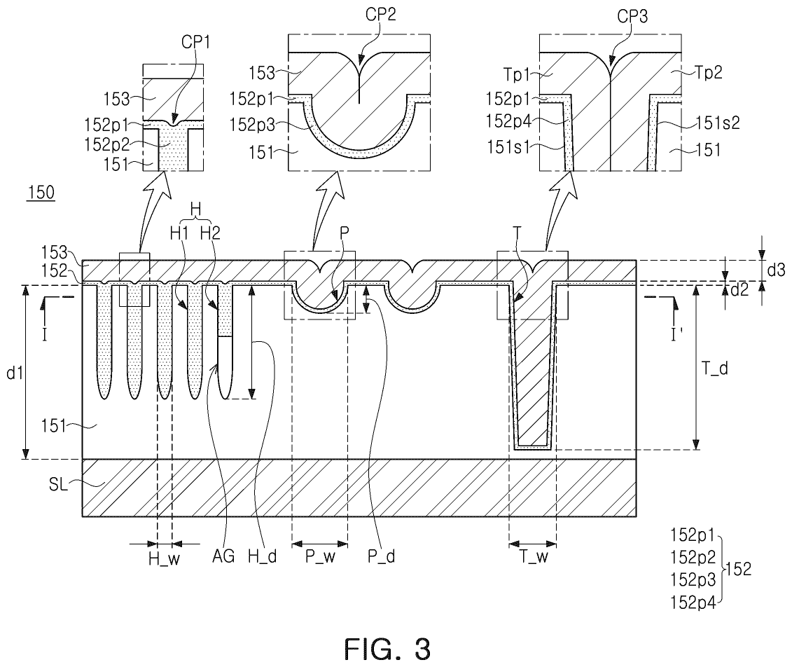

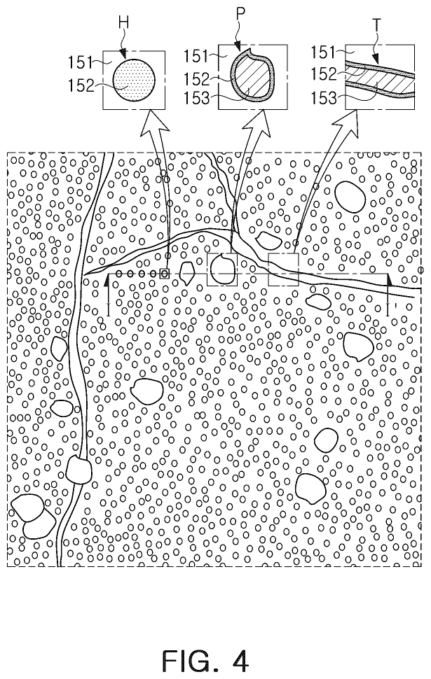

FIG. 3 is a partially enlarged view of a semiconductor processing facility 1 according to an example embodiment of the present inventive concept. FIG. 3 may be a partially enlarged view of region “A” including a body 150 of the first processing chamber 100 of FIG. 2. FIG. 3 is a cross-sectional view taken along line I-I′ of FIG. 4.

FIG. 4 is a schematic plan view of some components of the semiconductor processing facility 1 of FIG. 3. FIG. 4 may be a schematic plan view of a second protective layer 152 of FIG. 3.

Referring to FIG. 1, a semiconductor processing facility 1 may include a first processing chamber 100, a second processing chamber 200, and a connection pipe 300 connecting the first and second processing chambers 100 and 200 to each other.

The second processing chamber 200 may be a chemical vapor deposition (CVD) apparatus, performing a CVD technique. The second processing chamber 200 may be surrounded by a back plate 201 and a body 250. For example, the black plate 201 may cover a top surface of the second processing chamber 200 and the body 250 may cover side surfaces and a bottom surface of the second processing chamber 200. The second processing chamber 200 may include a shower head 220 and an electrostatic chuck 240. The shower head 220 may be disposed below the black plate 201. The electronic chuck 240 may be disposed below the shower head 220. A region between the back plate 201 and the shower head 220 may be defined as a plenum 210, and a region between the shower head 220 and the electrostatic chuck 240 may be defined as a treatment region 230. The shower head 220 may have a plurality of gas paths through which gas flows from the plenum 210 to the treatment region 230. A substrate W to be treated may be provided on an upper portion of the electrostatic chuck 240. The substrate W to be treated may include a semiconductor wafer. A discharge opening 260 may be disposed in a lower portion of the body 250.

The semiconductor processing facility 1 may include a plurality of second processing chambers 200.

The first processing chamber 100 may be an apparatus, cleaning the second processing chamber 200. The first processing chamber 100 may include a remote plasma source cleaning apparatus, which cleans chemical components remaining on an inner wall of the body 250 of the second processing chamber 200 by allowing cleaning gas to be in a plasma state and supplying the cleaning gas to the second processing chamber 200, but present inventive concept is not necessarily limited thereto.

In an example embodiment of the present inventive concept, processing gas may be injected into the first processing chamber 100, and the processing gas may be injected from the first processing chamber 100 into the second processing chamber 200. When a flowable chemical vapor deposition (FCVD) technique is performed by the second processing chamber 200, processing gas, which is used for the flowable chemical vapor deposition technique, may be injected from the first processing chamber 100 into the second processing chamber 200.

Referring to FIG. 2, the first processing chamber 100 may include a body 150 and a tube 110 defined by the body 150.

The tube 110 may include an injection opening 111, a discharge opening 115, and one or more tubes 112, 113a, 113b and 114 communicating with the injection opening 111 and the discharge opening 115. The injection opening 111, the discharge opening 115, and one or more tubes 112, 113a, 113b and 114 may be connected with each other and form an integrated structure. The one or more tubes 112, 113a, 113b, and 114 may be referred to as an injection pipeline 112, first and second injection connection pipelines 113a and 113b and a discharge pipeline 114. The first and second injection connection pipelines may communicate with the injection pipeline 112, and a discharge pipeline 114 may communicate with the first and second injection connection pipelines 113a and 113b. The discharge pipeline 114 may communicate with the discharge opening 115.

The cleaning gas or the processing gas may be injected into the injection opening 111.

The cleaning gas may include, for example, at least one of nitrogen trifluoride (NF₃), carbon tetrafluoride (CF₄), sulfur hexafluoride (SF₆), or argon (Ar), but the present inventive concept is not necessarily limited thereto. The cleaning gas may further include, for example, at least one of chlorine gas (Cl₂), hydrogen chloride (HCl), or oxygen (O₂).

The processing gas may be discharged through the discharge opening 115 to participate in a FCVD process in the second processing chamber 200. The processing gas may include a component, included in a nitride layer, on the substrate W to be treated. The processing gas may include, for example, ammonia (NH₃) gas.

Referring to FIG. 3, the body 150 may include a base layer SL and a plurality of protective layers 151, 152, and 153.

The base layer SL may include metal or a metal alloy. For example, the base layer SL may include aluminum or an aluminum alloy, but the present inventive concept is not necessarily limited thereto. The base layer SL may include, for example, stainless steel, titanium, a titanium alloy, yttrium, an yttrium alloy, magnesium, and/or a magnesium alloy.

The plurality of protective layers 151, 152, and 153 may include a first protective layer 151 on the base layer SL, a second protective layer 152 on the first protective layer 151, and a third protective layer 153 on the second protective layer 152.

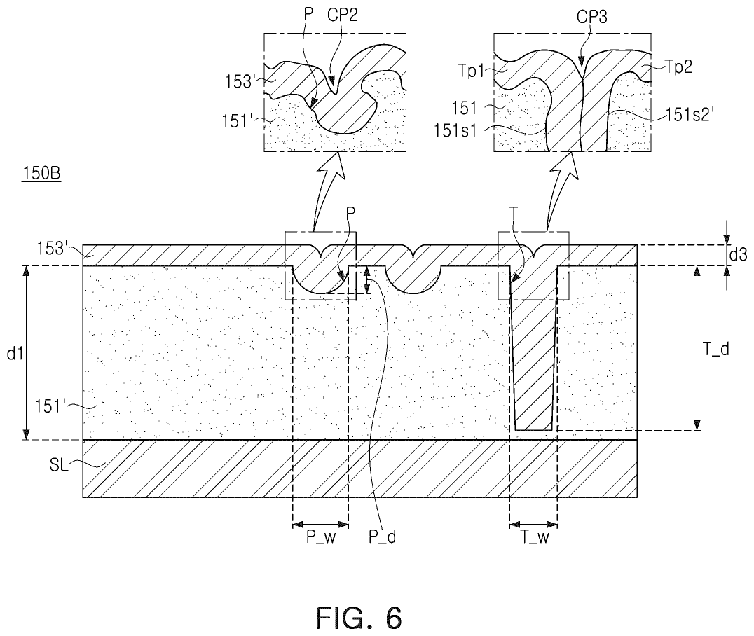

The first protective layer 151 may be formed on the base layer SL. The first protective layer 151 may include an anodized layer in which the base layer SL is anodized. In another example embodiment of the present inventive concept, the first protective layer 151 may include an electrolytic oxide layer in which the base layer SL is electrolytically oxidized (see FIG. 6). When the base layer SL includes aluminum or an aluminum alloy, the first protective layer 151 may include aluminum oxide (for example, Al₂O₃). When the base layer SL includes yttrium or an yttrium alloy, the first protective layer 151 may include yttrium oxide (for example, Y₂O₃). When the base layer SL includes magnesium or a magnesium alloy, the first protective layer 151 may include magnesium oxide (for example, MgO).

The first protective layer 151 may have a first thickness d1. The first thickness d1 may be about 300 μm or less. For example, in an example embodiment of the present inventive concept, the first thickness d1 may be in a range from about 5 μm to about 300 μm. For example, in an example embodiment of the present inventive concept, the first thickness d1 may be in a range from about 10 μm to about 200 μm.

Referring to FIG. 4 together, a surface of the first protective layer 151 may include a pore portion H, a pit portion P, and a tunnel portion T. The pore portion H, the pit portion P, and the tunnel portion T may be defects formed in a direction from an upper surface of the first protective layer 151 toward an upper surface of the base layer SL. The pore portion H, the pit portion P, and the tunnel portion T may be distinguished from each other. The first protective layer 151 may be disposed around the pore portion H, the pit portion P, and the tunnel portion T. The injection opening 111 and the discharge opening 115 may facilitate filling at least one of the pore portion H, the pit portion P, and the tunnel portion T.

The pore portion H may include a first pore portion H1 and a second pore portion H2. A width H_w of the pore portion H may be about 150 nm or less. In an example embodiment of the present inventive concept, the width H_w of the pore portion H may be in a range from about 5 nm to about 150 nm. For example, in an example embodiment of the present inventive concept, the width H_w of the pore portion H may be in a range from about 10 nm to about 100 nm. For example, the width H_w of the pore portion H may be in a range from about 10 nm to about 20 nm. The width H_w of the pore portion H may refer to a maximum width of the pore portion H, meaning a distance from a left sidewall to a right side wall of the pore portion H, where the pore portion H does not narrow down.

A depth H_d of the pore portion H may be substantially equal to or greater than the width H_w. In an example embodiment of the present inventive concept, the depth H_d of the pore portion H may be greater than the width H_w. For example, the depth H_d of the pore portion H may be greater than or equal to about 0.7 times the first thickness d1 of the first protective layer 151. For example, in an example embodiment of the present inventive concept, the depth H_d of the pore portion H may be in a range from about 0.75 to about 0.95 times the first thickness d1 of the first protective layer 151. For example, an end point of the pore portion H might not be in contact with the base layer SL, which is disposed on a bottom surface of the first protective layer 151.

A width P_w of the pit portion P may be about 20 μm or less. For example, in an example embodiment of the present inventive concept, the width P_w of the pit portion P may range from about 0.5 μm to about 15 μm. For example, in an example embodiment of the present inventive concept, the width P_w of the pit portion P may range from about 0.6 μm to about 15 μm. The width P_w of the pit portion P may refer to a maximum width of the pit portion P. For example, a width T_w of the pit portion P may refer to a longest straight-line distance across a region, measured between two points on an outer edges of the pit portion P that are farthest apart.

The depth P_d of the pit portion P may be substantially equal to or less than the width P_w of the pit portion P. In an example embodiment of the present inventive concept, the depth P_d of the pit portion P may be less than the width P_w of the pit portion P. The depth P_d of the pit portion P may be less than or equal to about 5 μm. For example, in an example embodiment of the present inventive concept, the depth P_d of the pit portion P may be in a range from about 0.1 μm to about 5 μm. For example, in an example embodiment of the present inventive concept, the depth P_d of the pit portion P may be in a range from about 0.1 μm to about 2 μm. The pit portion P may have a crater shape recessed in the upper surface of the first protective layer 151. According to an example embodiment of the present inventive concept, the pit portion P may be referred to as a pinhole portion.

The width T_w of the tunnel portion T may be about 5 μm or less. For example, in an example embodiment of the present inventive concept, the width T_w of the tunnel portion T may be in a range from about 0.5μm to about 5 μm. For example, in an example embodiment of the present inventive concept, the width T_w of the tunnel portion T may be in a range from about 0.6 μm to about 3 μm. The width T_w of the tunnel portion T may refer to the maximum width of the tunnel portion T.

A depth T_d of the tunnel portion T may be substantially equal to or greater than a width T_w of the tunnel portion T. In an example embodiment of the present inventive concept, a depth T_d of the tunnel portion T may be greater than a width T_w of the tunnel portion T. A depth T_d of the tunnel portion T may be substantially equal to or less than a thickness d1 of the first protective layer 151. For example, the tunnel portion T might not be in contact with the base layer SL, which is disposed on the bottom surface of the first protective layer 151. A depth H_d of the pore portion H may be less than the depth T_d of the tunnel portion.

The depth T_d of the tunnel portion T may be about 150 um or more. For example, in an example embodiment of the present inventive concept, the depth T_d of the tunnel portion T may be in a range from about 150 um to about 300 um.

A distance between the lowermost surface of the tunnel portion T and the upper surface of the base layer SL may be smaller than a distance between the lowermost surface of the pore portion H and the upper surface of the base layer SL and a distance between the lowermost surface of the pit portion P and the upper surface of the base layer SL, respectively. For example, the tunnel portion T may extend vertically from a top surface of the first protective layer 151, closer to the base layer SL than the pore portion H does.

The surface roughness of the first protective layer 151 may be about 1 μm or more. For example, in an example embodiment of the present inventive concept, the surface roughness of the first protective layer 151 may be in a range from about 2 μm to about 5 μm.

The second protective layer 152 may be disposed on the first protective layer 151. The second protective layer 152 may be a sealing layer sealing at least a portion of the defects, such as the pore portion H, the pit portion P, and the tunnel portion T formed in the surface of the first protective layer 151. The second protective layer 152 may be formed by one or more sealing techniques or a hybrid sealing technique in which the one or more sealing techniques are combined with each other. The sealing techniques may include sealing with deionized water vapor, sealing with nickel plating, sealing with polytetrafluoroethylene (PTFE), sealing with sodium silicate, sealing with chromium oxide (for example, Cr₂O₃), or sealing using a sol-gel process. The hybrid sealing technique may refer to a combination of two or more sealing techniques, among the sealing techniques described above, in an arbitrary order.

The second protective layer 152 may be defined as having a plurality of portions 152p1, 152p2, 152p3, and 152p4.

The plurality of portions 152p1, 152p2, 152p3, and 152p4 may include a first portion 152p1 extending along the surface of the first protective layer 151. The first portion 152p1 may have a second thickness d2. The second thickness d2 may be about 30 nm or less. For example, in an example embodiment of the present inventive concept, the second thickness d2 may be in a range from about 5 nm to about 30 nm. For example, in an example embodiment of the present inventive concept, the second thickness d2 may be in a range from about 5 nm to about 25 nm. For example, in an example embodiment of the present inventive concept, the second thickness d2 may be in a range from about 5 nm to about 20 nm. The second thickness d2 of the first portion 152p1 may be smaller than the first thickness d1 of the first protective layer 151.

The plurality of portions 152p1, 152p2, 152p3, and 152p4 may further include a second portion 152p2 connected to the first portion 152p1, the second portion 152p2 filling at least a portion of the pore portion H. When the pore portion H is entirely filled by the second portion 152p2, the pore portion H may be defined as a first pore portion H1. When the pore portion H is partially filled by the second portion 152p2, the pore portion H may be defined as a second pore portion H2. For example, an upper region of the second pore portion H2 may be partially filled by the second portion 152p2, and an air gap AG may be formed in a lower region of the second pore portion H2. The depth H_d of the second pore portion H2 may equal a combination of a depth of the second portion 152p2 and the depth of the air gap AG. The depth H_d of the first pore portion H1 may equal the depth of the second portion 152p2.

A first concave portion CP1 may be formed in an upper portion of the pore portion H. In another point of view, the second protective layer 152 may be defined as having a first concave portion CP1, concave toward the pore portion H from the upper portion of the pore portion H. A lower surface of the first concave portion CP1 may have a downwardly convex shape.

The plurality of portions 152p1, 152p2, 152p3, and 152p4 may further include a third portion 152p3 connected to the first portion 152p1, the third portion 152p3 filling at least a portion of the pit portion P. The third portion 152p3 may be connected to the first portion 152p1, and may extend along an inner wall of the pit portion P. For example, the third portion 152p3 may have a crater shape recessed in the upper surface of the first protective layer 151. The third portion 152p3 may be disposed on the inner wall of the pit portion P. The third portion 152p3 may have a thickness, which is substantially equal to that of the second thickness d2 of the first portion 152p1.

The plurality of portions 152p1, 152p2, 152p3, and 152p4 may further include a fourth portion 152p4 connected to the first portion 152p1, the fourth portion 152p4 filling at least a portion of the tunnel portion T. The fourth portion 152p4 may be connected to the first portion 152p1, and may extend along an inner wall of the tunnel portion T. The fourth portion 152p4 may be disposed on the inner wall of the tunnel portion T. The fourth portion 152p4 may have a thickness, which is substantially equal to that of the second thickness d2 of the first portion 152p1.

A surface roughness of the second protective layer 152 may be less than that of the first protective layer 151. The surface roughness of the second protective layer 152 may be about 2 μm or less. For example, in an example embodiment of the present inventive concept, the surface roughness of the second protective layer 152 may be in a range from about 0.5 μm to about 2 μm.

The third protective layer 153 may be disposed on the second protective layer 152 and define the tube 110.

The third protective layer 153 may conformally extend along a surface of the second protective layer 152, and may fill a remaining portion of the pit portion P. The third protective layer 153 may conformally extend in the pit portion P.

A second concave portion CP2 may be formed in an upper portion of the pit portion P. In another point of view, the third protective layer 153 may be defined as having a second concave portion CP2, concave toward the pit portion P from the upper portion of the pit portion P. A lower surface of the second concave portion CP2 may have a downwardly pointed shape.

The third protective layer 153 may conformally extend along the surface of the second protective layer 152, and may fill a remaining portion of the tunnel portion T. The pit portion T may have a first side 151s1 and a second side 151s2 opposite to the first side s1. The third protective layer 153 may include a first portion Tp1 disposed on the first side 151s1, the first portion Tp1 extending to the surface (for example, an upper surface) of the second protective layer 152, and a second portion Tp2 disposed on the second side 151s2, the second portion Tp2 extending to the surface (for example, an upper surface) of the second protective layer 152. In cross-sectional view, a boundary line extending in a depth direction of the tunnel portion T may be observed between the first and second portions Tp1 and Tp2. An uppermost surface of the first portion Tp1 and an uppermost surface of the second portion Tp2 may be positioned on substantially the same level with respect to the upper surface of the base layer SL.

The third protective layer 153 may have a third thickness d3. The third thickness d3 may be about 2 μm or less. For example, in an example embodiment of the present inventive concept, the third thickness d3 may be in a range from about 0.5 μm to about 2 μm. For example, in an example embodiment of the present inventive concept, the third thickness d3 may be in a range from about 0.5 μm to about 1.5 μm.

A depth of the tunnel portion T may be defined to have a first gap at a depth in a vertical direction. At least a portion of each of the first and second portions Tp1 and Tp2 may have a thickness substantially equal to or greater than that of half of the first gap.

A third concave portion CP3 may be formed on the tunnel portion T. In another point of view, the third protective layer 153 may be defined as having a third concave portion CP3, concave toward the tunnel portion T from an upper portion of the tunnel portion T. A lower surface of the third concave portion CP3 may have a downwardly pointed shape.

A surface roughness of the third protective layer 153 may be less than that of the second protective layer 152. The surface roughness of the third protective layer 153 may be about 1 μm or less. For example, in an example embodiment, the surface roughness of the third protective layer 153 may be in a range from about 0.1 μm to about 1 μm. For example, in an example embodiment, the surface roughness of the third protective layer 153 may be in a range from about 0.3 μm to about 0.8 μm.

Referring back to FIG. 2, the first processing chamber 100 may further include an ignitor 160.

Cleaning gas, injected into the injection opening 111, may be ignited by the ignitor 160, transferred in a plasma state and discharged to the discharge opening 115. The ignitor 160 may be mounted at an end of an injection pipeline 112, that is, at a connection portion between the injection pipeline 112 and a first injection connection pipeline 113a. However, a position at which the ignitor 160 is mounted is not necessarily limited thereto.

Referring back to FIG. 2, the first processing chamber 100 may further include a magnetic body 170.

The magnetic body 170 may form a magnetic field in the tube 110. The magnetic body 170 may include a ferrite core. Plasma, caused by cleaning gas passing through the tube 110 due to the magnetic body 170, may be distributed at a uniform density.

Referring back to FIG. 2, the first processing chamber 100 may include a plurality of blocks.

For example, the first processing chamber 100 may be a component in which first to fourth blocks 100a, 100b, 100c, and 100d are combined with each other. For example, the first processing chamber 100 may be a component in which the first block 100a having an injection opening 111 and the injection pipeline 112, the second and third blocks 100b and 100c respectively having portions of the first and second injection connection pipelines 113a and 113b, and the fourth block 100a having a discharge opening 115 and a discharge pipeline 114. For example, the first to fourth blocks 100a, 100b, 100c and 100d may be stacked on top of each other, with the first block 100a being on top. The first to fourth blocks 100a, 100b, 100c, and 100d may be combined with each other to form a magnetic body coupling space having a predetermined empty space, and the magnetic body 170 may be positioned in the magnetic body coupling space to provide the first processing chamber 100. However, the number and shape of the plurality of blocks are not necessarily limited to those described above.

Referring back to FIG. 1, the semiconductor processing facility 1 may further include a baffle plate PT provided on the first processing chamber 100.

The baffle plate PT may include a baffle plate body B_PT and a first flow path FP1 defined by the baffle plate body B_PT. The baffle plate PT may be provided on a lower portion of the first processing chamber 100, such that the first flow path FP1 may communicate with the discharge opening 115. For example, the discharge opening 115 of the first processing chamber 100 may face the first flow path FP1 of the baffle plate PT. The first flow path FP1 may have a cylindrical shape, connecting upper and lower portions of the baffle plate PT to each other, but the present inventive concept is not necessarily limited thereto.

A baffle plate body B_PT of the baffle plate PT may have a configuration, substantially the same as that of the body 150 of the first processing chamber 100 described with reference to FIG. 3. For example, the body B_PT of the baffle plate PT may include a base layer corresponding to a base layer (“SL” of FIG. 3), a first protective layer corresponding to a first protective layer (“151” of FIG. 3), a second protective layer corresponding to a second protective layer (“152” of FIG. 3), and a third protective layer corresponding to a third protective layer (“153” of FIG. 3). The third protective layer of the baffle plate body B_PT may define the first flow path FP1.

Referring back to FIG. 1, the semiconductor processing facility 1 may further include a distributor DB provided on the baffle plate PT.

The distributor DB may include a distributor body B_DB and a second flow path FP2 defined by the distributor body B_DB. The distributor DB may be provided on a lower portion the baffle plate PT, such that the second flow path FP2 may communicate with the first flow path FP1. For example, the second flow path FP2 of the distributor DB may face the first flow path FP1 of the baffle plate PT. The second flow path FP2 may include an injection path formed in an upper portion of the baffle plate PT, and a plurality of discharge paths obtained by dividing the injection path into a plurality of portions, the plurality of discharge paths formed on a side portion of the baffle plate PT. The plurality of discharge paths may be formed on the side portion of the baffle plate PT to be spaced apart from each other. The distributor DB may distribute cleaning gas or processing gas, injected into the injection opening 111 of the first processing chamber 100, to each of the plurality of second processing chambers 200.

The distributor body B_DB of the distributor DB may have a configuration, substantially the same as that the body 150 of the first processing chamber 100 described with reference to FIG. 3. For example, the body B_DB of the distributor DB may include a base layer corresponding to a base layer (“SL” of FIG. 3), a first protective layer corresponding to a first protective layer (“151” of FIG. 3), a second protective layer corresponding to a second protective layer (“152” of FIG. 3), and a third protective layer corresponding to a third protective layer (“153” of FIG. 3). The third protective layer of the distributor body B_DB may define the second flow path FP2.

The semiconductor processing facility 1 may further include a plurality of connection pipe 300 provided between the first processing chamber 100 and the second processing chamber 200.

Each of the plurality of connection pipe 300 may connect the first processing chamber 100 and each of the plurality of second processing chambers 200 to each other. Each of the plurality of connection pipe 300 may connect the second flow path FP2 of the distributor DB and each of the plurality of second processing chambers 200 to each other.

According to an embodiment of the present inventive concept, by forming a plurality of protective layers 151, 152, and 153, in particular the second and third protective layers 152 and 153 that fills defects, such as the pore portion H, the pit portion P, and the tunnel portion T, the semiconductor processing facility 1 may include the body 150 with minimized exposure of a substrate layer SL and reduced surface roughness.

As the exposure of the substrate layer SL is minimized, deterioration of the substrate layer SL due to a cleaning gas component (e.g., fluorine) in a plasma state can be reduced, and thus the lifespan of the semiconductor process facility 1 including the first process chamber 100 can be increased.

In addition, as the surface roughness decreases, a phenomenon of the processing gas injected into the inject opening 111 of the first processing chamber 100 being adsorbed on a surface of the body 150 may be reduced. Accordingly, an absolute amount of processing gas flowing into the second processing chamber 200 may be substantially the same as an absolute amount of processing gas injected into the first processing chamber 100.

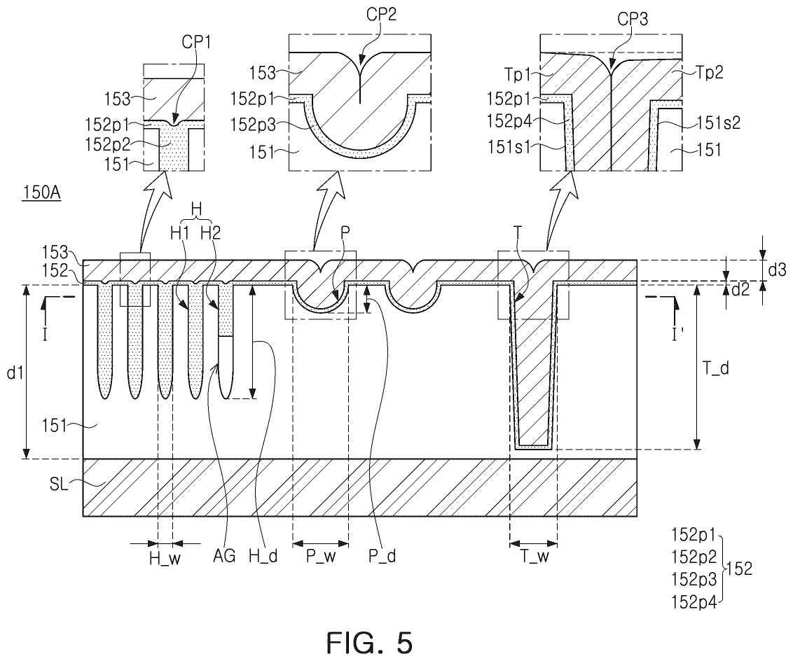

FIG. 5 is a partially enlarged view of a semiconductor processing facility according to an example embodiment of the present inventive concept. FIG. 5 may be a partially enlarged view of a body 150A of a first processing chamber 100 according to an example embodiment of the present inventive concept.

The body 150A of the first processing chamber 100 of FIG. 5 may be the same as or similar to that described with reference to FIGS. 1 to 4, except that a first portion Tp1 and a second portion Tp2 of a third protective layer 153 are positioned on different levels. To the extent that an element has not been described in detail, it may be assumed that the element is at least similar to corresponding elements that have been described in FIGS. 1 through 4.

An upper surface of a first protective layer 151 may include a plurality of portions on different levels with respect to an upper surface of a base layer SL in the vicinity of a tunnel portion T. In another point of view, the upper surface of the first protective layer 151 might not be flat. Accordingly, second and third protective layers 152 and 153 may also include a plurality of portions on different levels with respect to the upper surface of the base layer SL. For example, with respect to the upper surface of the base layer SL, an uppermost surface of the first portion Tp1 of the third protective layer 153 may be on a higher level than an uppermost surface of the second portion Tp2 of the third protective layer 153.

FIG. 6 is a partially enlarged view of a semiconductor processing facility according to an example embodiment of the present inventive concept. FIG. 6 may be a partially enlarged view of a body 150B of a first processing chamber 100 according to an example embodiment of the present inventive concept.

The body 150B of the first processing chamber 100 of FIG. 6 may be the same as or similar to that described with reference to FIGS. 1 to 5, except that a pit portion P and a tunnel portion T may be limitedly formed in a surface of a first protective layer 151′. To the extent that an element has not been described in detail, it may be assumed that the element is at least similar to corresponding elements that have been described in FIGS. 1 through 5.

In an embodiment of the present inventive concept, the first protective layer 151′ may include an electrolytic oxide layer in which a base layer SL is electrolytically oxidized. In a similar manner to that described with reference to FIGS. 1 to 4, when the base layer SL includes aluminum or an aluminum alloy, the first protective layer 151′ may include aluminum oxide (for example, Al₂O₃). When the base layer SL includes yttrium or an yttrium alloy, the first protective layer 151′ may include yttrium oxide (for example, Y₂O₃). When the base layer SL includes magnesium or a magnesium alloy, the first protective layer 151′ may include magnesium oxide (for example, MgO).

When compared to embodiments that are described with reference to FIGS. 1 to 4, a surface roughness of the first protective layer 151′ may be greater than that of a first protective layer (“151” of FIG. 3). The surface roughness of the first protective layer 151′ may be about 1 μm or more. For example, in an example embodiment of the present inventive concept, the surface roughness of the first protective layer 151′ may be in a range from about 1 μm to about 5 μm. For example, in an example embodiment of the present inventive concept, the surface roughness of the first protective layer 151′ may be in a range from about 1 μm to about 3 μm. For example, in an example embodiment of the present inventive concept, the surface roughness of the first protective layer 151′ may be in a range from about 1.2 μm to about 2.5 μm.

When compared to that described with reference to FIGS. 1 to 4, a surface roughness of a third protective layer 153′ may be greater than that of a third protective layer (“153” of FIG. 3). The surface roughness of the third protective layer 153′ may be about 2 μm or less. In an example embodiment of the present inventive concept, the surface roughness of the third protective layer 153′ may be in a range of about 0.1 μm to about 2 μm. In an example embodiment of the present inventive concept, the surface roughness of the third protective layer 153′ may be in a range of about 1.2 μm to about 1.7 μm.

In the present example embodiment, a pit portion P and a tunnel portion T may be limitedly formed in a surface of the first protective layer 151′. In another point of view, when compared to that described with reference to FIGS. 1 to 4, a pore portion (“H” of FIG. 3) might not be formed in the surface of the first protective layer 151′. Accordingly, in the present example embodiment, the body 150B of the first processing chamber 100 might not include a second protective layer (“152” of FIG. 1).

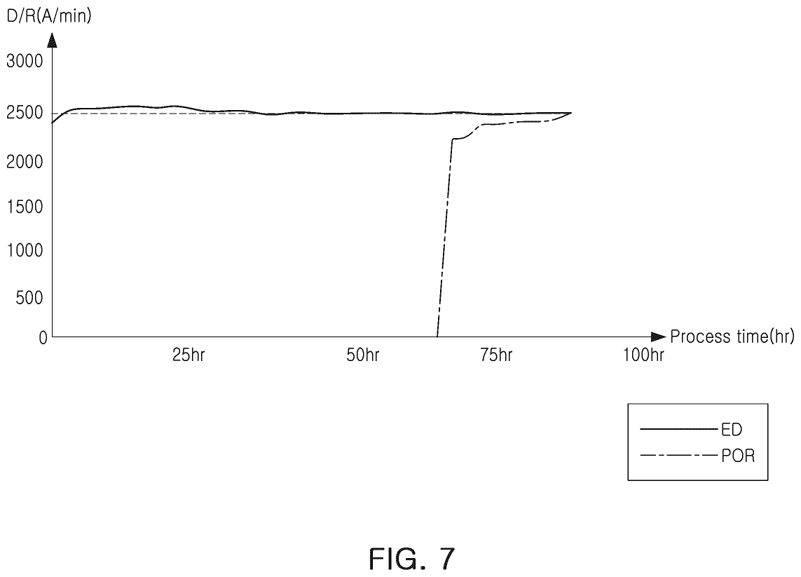

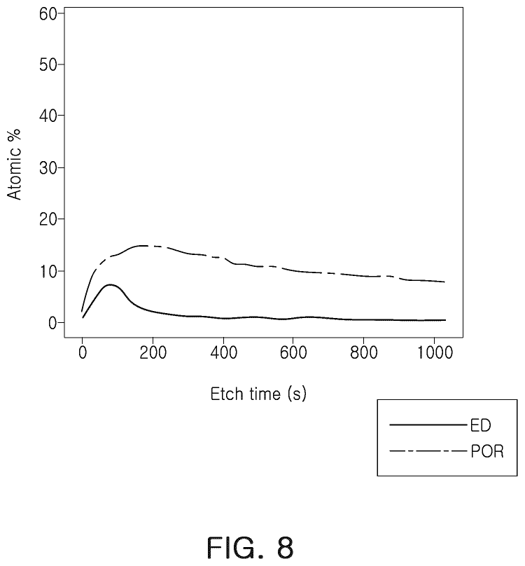

Each of FIGS. 7 and 8 may be an experimental result using a semiconductor processing facility (“1” of FIG. 1) including a body (“150” of FIG. 3) of the present inventive concept.

FIG. 7 is a graph illustrating a comparison between a deposition rate (D/R) for a substrate to be treated (“W” of FIG. 1) over processing time using a semiconductor processing facility according to the related art (“POR” of FIG. 7) and a deposition rate (D/R) for a substrate to be treated (“W” of FIG. 1) over processing time of a semiconductor processing facility according to an example embodiment of the present inventive concept (“ED” of FIG. 7).

Referring to FIG. 7, in the semiconductor processing facility according to the related art, it may be interpreted that deposition is performed on a substrate to be treated only after a processing time ranging from about 50 hours to about 75 hours (“POR” of FIG. 7).

In the semiconductor processing facility (“1” of FIG. 1) according to an example embodiment of the present inventive concept, it may be interpreted that deposition is performed on a substrate to be treated (“W” of FIG. 1) without delay time (“ED” of FIG. 7). The above-described experimental results may be interpreted that as a surface roughness of a body (“150” of FIG. 3) of the present inventive concept decreases, a phenomenon in which processing gas is adsorbed onto a surface of the body (“150” of FIG. 3) decreases, and thus an absolute amount of processing gas discharged to a second processing chamber (“200” of FIG. 1) is maintained as compared to an absolute amount of processing gas injected into the first processing chamber (“100” of FIG. 1).

FIG. 8 is a graph illustrating a comparison between a percentage of a concentration of a fluorine element present in a defect, for example, a tunnel portion (“T” of FIG. 3), using a semiconductor processing facility (“1” of FIG. 1) according to the related art (“POR” of FIG. 8) and a percentage of a concentration of a fluorine element present in the defect, for example, the tunnel portion (“T” of FIG. 3), using a semiconductor processing facility (“1” of FIG. 1) according to an example embodiment of the present inventive concept (“ED” of FIG. 8).

The fluorine element may be one of elements included in cleaning gas that is in a plasma state, and the percentage of the concentration of the fluorine element may refer to a percentage of a concentration of a fluorine element present in a depth direction of the tunnel portion (“T” of FIG. 3). The fluorine element concentration percentage was measured using X-ray photoelectron spectroscopy (XPS).

Referring to FIG. 8, in the semiconductor processing facility according to the related art, it may be interpreted that the percentage of the concentration of fluorine element present in the defect does not significantly vary depending on a depth direction of the defect (“POR” of FIG. 8).

In the semiconductor processing facility (“1” of FIG. 1) according to an example embodiment of the present inventive concept, it may be interpreted that the percentage of the concentration of the fluorine element present in the tunnel portion (“T” of FIG. 3) is substantially zero below a predetermined depth (“ED” of FIG. 8).

The above-described experimental results may be interpreted that permeation of the fluorine element into the first protective layer 151 and the base layer SL is significantly reduced as a body (“150” of FIG. 3) of the present inventive concept includes a plurality of protective layers 151, 152, and 153, in particular, the second and third protective layers 152 and 153.

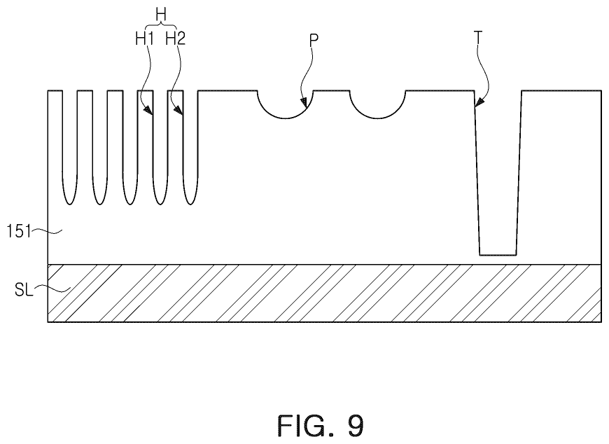

FIGS. 9, 10, and 11 are cross-sectional views of sequential processes in a method of manufacturing a semiconductor processing facility according to an example embodiment of the present inventive concept. FIGS. 9, 10, and 11 are cross-sectional views illustrating a method of manufacturing the first processing chamber 100 including the body 150 according to a process order.

Referring to FIG. 9, a base layer SL may be provided, and a first protective layer 151 may be formed on the base layer SL.

The base layer SL may include metal or a metal alloy. The base layer SL may include, for example, aluminum or an aluminum alloy.

A first protective layer 151 may be formed on the base layer SL. The first protective layer 151 may be formed by anodization treatment. The anodization treatment may include soft anodization or hard anodization. The first protective layer 151 may be formed on the base layer SL by immersing the base layer SL in a liquid electrolyte, and applying current using the base layer SL as an anode and the auxiliary electrode as a cathode. In this case, the first protective layer 151 may be referred to as an anodization layer.

Defects including a pore portion H, a pit portion P, and a tunnel portion T may be formed in a surface of the first protective layer 151.

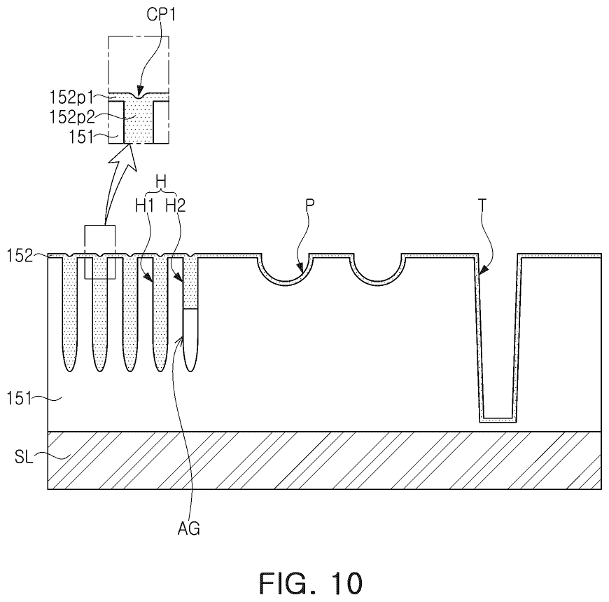

Referring to FIG. 10, a second protective layer 152 may be formed on the first protective layer 151.

The second protective layer 152 may be formed by one or more sealing techniques or a hybrid sealing technique in which the one or more sealing techniques are combined with each other. The sealing techniques may include sealing with deionized water vapor, sealing with nickel plating, sealing with polytetrafluoroethylene (PTFE), sealing with sodium silicate, sealing with chromium oxide (for example, Cr₂O₃), or sealing using a sol-gel process. The hybrid sealing technique may refer to a combination of two or more sealing techniques, among the sealing techniques described above, in an arbitrary order. The second protective layer 152 may be referred to as a sealing layer.

The second protective layer 152 may seal at least a portion of the defects including the pore portion H, the pit portion P, and the tunnel portion T. For example, the second protective layer 152 may entirely seal a first pore portion H1, and may fill an upper region of a second pore portion H2. A first concave portion CP1 having a downwardly convex-shaped lower surface may be formed on the pore portion H. The second protective layer 152 may be formed on an inner wall of each of the pit portion P and the tunnel portion T. For example, the second protective layer 152 may have a concave shape that curves towards the base layer SL.

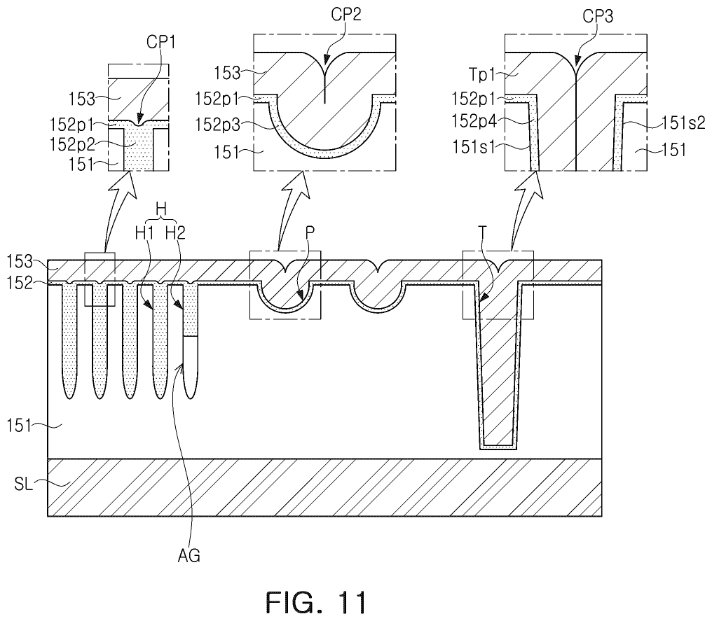

Referring to FIG. 11, a third protective layer 153 may be formed on the second protective layer 152.

The third protective layer 153 may be formed using CVD or atomic layer deposition (ALD). The third protective layer 153 may cover the first concave portion CP1 of the second protective layer 152, and may fill a remaining portion of each of the pit portion P and the tunnel portion T. The third protective layer 153 having a conformal thickness may be formed on an upper surface of the second protective layer 152. The third protective layer 153 may include at least one of aluminum oxide (Al₂O₃), yttrium oxide (Y₂O₃), yttrium oxyfluoride (YOF), silicon carbide (SiC), or yttrium aluminum garnet (YAG).

A second concave portion CP2 having a downwardly pointed-shaped lower surface may be formed on the pit portion P, and a third concave portion CP3 having a downwardly pointed-shaped lower surface may be formed on the tunnel portion T.

In the vicinity of the tunnel portion T, the third protective layer 153 may have first and second portions Tp1 and Tp2 respectively having uppermost surfaces positioned on substantially the same level with respect to an upper surface of the base layer SL. For example, in respect to the third concave portion CP3, the first portion Tp1 and the second portion Tp2 may have a same vertical height. The uppermost surfaces of the first and second portions Tp1 and Tp2 may be formed to be on different levels with respect to the upper surface of the base layer SL (see FIG. 5).

Hereinafter, referring to FIGS. 2 and 3 together, a plurality of blocks 100a, 100b, 100c, and 100d, respectively having a body 150 including a base layer SL and a plurality of protective layers 151, 152, and 153, may be provided. The plurality of blocks 100a, 100b, 100c, and 100d may be combined with each other such that a tube 110 is defined, thereby providing a first processing chamber 100. The tube 110 may be defined by a third protective layer 153 of the body 150.

Referring to FIG. 1 together, in a similar manner to that described with reference to FIGS. 9 to 11, a baffle plate PT, including a body (“B_PT” of FIG. 1) including a base layer corresponding to a base layer (“SL” of FIG. 11) and a plurality of protective layers corresponding to a plurality of protective layers (“151, 152, and 153” of FIG. 11), may be provided. A first flow path FP1 may be defined by an uppermost protective layer, among the plurality of protective layers.

Similarly, a distributor DB including a body (“B_DB” of FIG. 1) including a base layer corresponding to a base layer (“SL” of FIG. 11) and a plurality of protective layers corresponding to a plurality of protective layers (“151, 152, and 153” of FIG. 11), may be provided. A second flow path FP2 may be defined by an uppermost protective layer, among the plurality of protective layers.

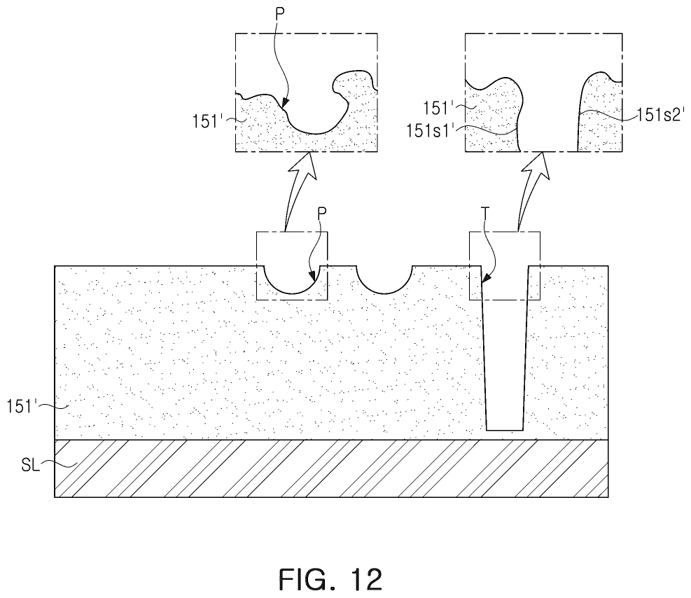

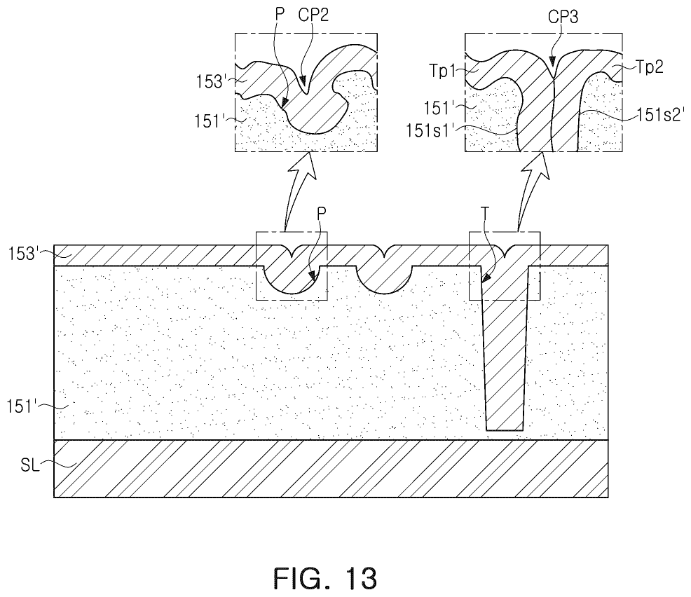

FIGS. 12 and 13 are cross-sectional views of sequential processes in a method of manufacturing a semiconductor processing facility according to an example embodiment of the present inventive concept. FIGS. 12 and 13 are cross-sectional views of sequential processes in a method of manufacturing a first processing chamber 100 including a body 150B.

Referring to FIG. 12, a base layer SL may be provided, and a first protective layer 151′ may be formed on the base layer SL.

The base layer SL may include metal or a metal alloy. The base layer SL may include, for example, aluminum or an aluminum alloy.

A first protective layer 151′ may be formed on the base layer SL. The first protective layer 151′ may be formed using electrolytic oxidation treatment. The electrolytic oxidation treatment may be plasma electrolytic oxidation (PEO). In this case, a surface roughness of the first protective layer 151′ may be greater than that of the first protective layer 151 described with reference to FIG. 9. The first protective layer 151′ may be referred to as a plasma electrolytic oxide layer.

Defects, including a pit portion P and a tunnel portion T, may be formed in a surface of the first protective layer 151′.

Referring to FIG. 13, a third protective layer 153 may be formed on the first protective layer 151′.

The third protective layer 153 may be formed using CVD or ALD. The third protective layer 153 having a conformal thickness may be formed on an upper surface of the second protective layer 152, and may cover inner walls of the pit portion P and the tunnel portion T. The third protective layer 153 may include at least one of aluminum oxide (Al₂O₃), yttrium oxide (Y₂O₃), yttrium oxyfluoride (YOF), silicon carbide (SiC), or yttrium aluminum garnet (YAG).

A second concave portion CP2 having a downwardly pointed-shaped lower surface may be formed on the pit portion P, and a third concave portion CP3 having a downwardly pointed-shaped lower surface may be formed on the tunnel portion T.

According to example embodiments of the present inventive concept, a semiconductor processing facility 1 including a processing chamber 100 having a body 150 including a plurality of protective layers 151, 152, and 153, and a method of manufacturing the semiconductor processing facility 1 may be provided.

Specifically, by forming the plurality of protective layers 151, 152, and 153 that fills ate last a portion of defects, such as the pore portion H, the pit portion P, and the tunnel portion T, the processing chamber 100 of the semiconductor processing facility 1 having reduced surface roughness may be provided.

While example embodiments of the present inventive concept have been shown and described above, it will be apparent to those skilled in the art that modifications and variations could be made without departing from the scope of the present inventive concept as defined by the appended claims.

What is claimed is:

1. A semiconductor processing facility comprising:
a body and a tube,
wherein the body comprises:
a base layer;
a first protective layer disposed on the base layer, wherein the first protective layer having at least one of a pore portion, a pit portion, and a tunnel portion;
a second protective layer disposed on the first protective layer, wherein the second protective layer fills in the at least one of the pore portion, the pit portion, and the tunnel portion; and
a third protective layer disposed on the second protective layer, wherein the third protective layer defines the tube.

2. The semiconductor processing facility of claim 1, wherein
the base layer comprises at least one of aluminum (Al) or an aluminum alloy, and
the first protective layer comprises aluminum oxide.

3. The semiconductor processing facility of claim 1, wherein the second protective layer comprises:
a first portion extending along an upper surface of the first protective layer; and
a second portion connected to the first portion, wherein the second portion fills the pore portion.

4. The semiconductor processing facility of claim 3, wherein the second protective layer has a first concave portion, concaving towards the pore portion from an upper portion of the second portion of the pore portion.

5. The semiconductor processing facility of claim 3, wherein
the second portion fills an upper region of the pore portion, and
an air gap is formed in a lower region of the pore portion.

6. The semiconductor processing facility of claim 3,
wherein the second protective layer further comprises a third portion connected to the first portion, and
wherein the third portion is disposed on an inner wall of the pit portion.

7. The semiconductor processing facility of claim 3,
wherein the second protective layer further comprises a fourth portion connected to the first portion, and
wherein the fourth portion is disposed on an inner wall of the tunnel portion.

8. The semiconductor processing facility of claim 3, wherein a thickness of the first portion of the second protective layer ranges from about 5 nm to about 20 nm.

9. The semiconductor processing facility of claim 1, wherein
the third protective layer fills a remaining portion of the pit portion, and
the third protective layer has a second concave portion, concaving towards the pit portion from an upper portion of the pit portion.

10. The semiconductor processing facility of claim 1, wherein
the third protective layer fills a remaining portion of the tunnel portion,
the tunnel portion includes a first side and a second side disposed opposite to the first side, and
the third protective layer comprises:
a first portion on the first side, wherein the first portion extends to an upper surface of the second protective layer; and
a second portion on the second side, wherein the second portion extends to an upper surface of the second protective layer.

11. The semiconductor processing facility of claim 10, wherein uppermost surfaces of the first and second portions are disposed on different levels with respect to the base layer.

12. The semiconductor processing facility of claim 10, wherein
the tunnel portion has a first gap, and
each of the first and second portions has a thickness, which is substantially equal to or greater than half of the first gap of the tunnel portion.

13. The semiconductor processing facility of claim 1, wherein the third protective layer has a third concave portion, concaving towards the tunnel portion from an upper portion of the tunnel portion.

14. The semiconductor processing facility of claim 1, wherein
a width of the pore portion ranges from about 10 nm to about 100 nm, and
a width of each of the pit portion and the tunnel portion ranges from about 0.5 um to about 15 um.

15. The semiconductor processing facility of claim 14, wherein
a depth of the pore portion is greater than the width of the pore portion, and
a depth of the tunnel portion is greater than the width of the tunnel portion.

16. A semiconductor processing facility comprising:
a plasma chamber body and a tube defined by the plasma chamber body,
wherein the plasma chamber body comprises:
a base layer;
a first protective layer disposed on the base layer, wherein the first protective layer having at least one of a pit portion and a tunnel portion, and the tunnel portion has a first side and a second side disposed opposite to the first side; and
a second protective layer disposed on the first protective layer,
wherein the second protective layer fills in at least a portion of the pit portion,
wherein the second protective layer comprises a first portion on the first side of the tunnel portion, and a second portion on the second side of the tunnel portion, and
wherein a concave portion is defined by the first and second portions, between the first and second portions.

17. The semiconductor processing facility of claim 16, wherein a surface roughness of the second protective layer is less than a surface roughness of the first protective layer.

18. The semiconductor processing facility of claim 16, wherein a width of at least one of the pit portion and the tunnel portion ranges from about 0.5 um to about 15 um.

19. A semiconductor processing facility comprising:
a plasma chamber,
wherein the plasma chamber comprises:
a plasma chamber body, and
a tube having an injection opening, a discharge opening, and at least one tube communicating with the injection opening and the discharge opening, the tube defined by the plasma chamber body;
a baffle plate disposed on the plasma chamber, wherein the baffle plate comprises a baffle plate body, and a first flow path communicates with the discharge opening of the plasma chamber; and
a distributor on the baffle plate, wherein the distributor comprises a distributor body, and at least one second flow path communicating with the first flow path of the baffle plate, and
wherein each of the plasma chamber body, the baffle plate body, and the distributor body comprises:
a base layer;
a first protective layer disposed on the base layer, wherein the first protective layer having at least one of a pore portion, a pit portion, and a tunnel portion;
a second protective layer disposed on the first protective layer, wherein the second protective layer fills in the at least one of the pore portion, the pit portion, and the tunnel portion; and
a third protective layer disposed on the second protective layer.

20. The semiconductor processing facility of claim 19, wherein
the second flow path comprises a plurality of second flow paths, and further comprising a plurality of processing chambers respectively connected to the plurality of second flow paths.
